(19) United States
(12) Patent Application Publication
(10) Pub. No.: US 2015/0362840 A1
(43) Pub. Date: Dec. 17, 2015

(54) MASK PLATE AND METHOD FOR MANUFACTURING COLOR FILTER UNIT OF COLOR FILTER SUBSTRATE

(71) Applicants: Boe Technology Group Co., Ltd., Beijing (CN); Beijing Boe Display Technology Co., Ltd., Beijing (CN)

(72) Inventors: He FENG, Beijing (CN); Hongjiang WU, Beijing (CN); Sikai ZHANG, Beijing (CN); Min LI, Beijing (CN)

(21) Appl. No.: 14/497,464

(22) Filed: Sep. 26, 2014

(30) Foreign Application Priority Data
Jun. 11, 2014 (CN) 201410258156.X

(51) Int. Cl. G03F 7/40; G03F 1/00

(52) U.S. Cl. CPC G03F 7/40; G03F 1/00

(57) ABSTRACT

A mask plate used for manufacturing a color filter unit of a color filter substrate, the followings are formed thereon: an un-blocked area, corresponding to a first area of positive photoresist surrounding the color filter unit forming area of the color filter unit; at least one partially blocked area through which the light is able to pass partially, the at least one partially blocked area corresponding to a second area of the positive photoresist, the second area is a part of the color filter unit forming area, the at least one partially blocked area is adjacent to the un-blocked area at a common edge; an entirely blocked area, corresponding to a third area of the positive photoresist, the third area is another part of the color filter unit forming area; the reserved photoresist in the second area and the third area form the color filter unit.

### CROSS-REFERENCE OF RELATED APPLICATIONS

The present disclosure claims priority of the Chinese patent application No.201410258156.X filed on Jun. 11, 2014, which is incorporated herein by reference in its entirety.

### TECHNICAL FIELD

The present disclosure relates to the field of color filter substrate manufacturing technology, in particular relates to a mask plate and a method for manufacturing a color filter unit of a color filter substrate.

### BACKGROUND

In a conventional manufacturing process for a color filter substrate, there is segment difference in an RGB layer (a color filter unit). Taking an order of RGB for example, when a Green layer (a green pixel layer) 2 is manufactured after a Red layer (a red pixel layer) has been finished, the segment difference of the Green layer 2 at a side close to the red layer 1 is increased due to a film layer existing at the side of the Green layer close to the Red layer 1. When manufacturing the Blue layer 3, the segment differences at the both sides of the Blue layer 3 are increased due to thick film layers existing at both sides of the Blue layer 3, as shown in FIG. 1.

### SUMMARY

In order to solve the above-mentioned technical problems, the present disclosure provides a mask plate and a method for manufacturing a color filter unit of a color filter substrate, so as to achieve the object of reducing a corner segment difference.

In order to achieve the above-mentioned object, the present disclosure adopts a technical solution of: a mask plate, configured to manufacturing a color filter unit of a color filter substrate, on the mask plate, the followings is formed:

an un-blocked area, through which light is able to entirely pass, the un-blocked area corresponding to a first area of positive photoresist surrounding a color filter forming area in which the color filter unit is to be formed;

at least one partially blocked area, through which the light is able to partially pass, the at least one partially blocked area corresponding to a second area of the positive photoresist, the second area is a part of the color filter forming area, the at least one partially blocked area is adjacent to the un-blocked area at a common edge;

an entirely blocked area, through which the light cannot pass at all, the entirely blocked area corresponding to a third area of the positive photoresist, the third area is another part of the color filter unit forming area;

wherein the color filter unit is formed by photoresist reserved in the second area and the third area.

Furthermore, the second area corresponding to each partially blocked area is adjacent to the first area at an adjacent edge of the first area and corresponds to a color filter unit which is formed in the periphery of the first area and adjacent to the adjacent edge.

The present disclosure also provides a method for manufacturing a color filter unit of the color filter substrate, including:

photoresist coating step, forming a layer of positive photoresist on a substrate, the positive photoresist being used to form the color filter unit;

exposing step, entirely exposing, partially exposing and blocking exposure on the first area, the second area and the third area of the positive photoresist respectively, the first area being an area surrounding a color filter unit forming area in which the color filter unit is to be formed, the second area is a part of the color filter unit forming area and is adjacent to the first area at a common edge, and the third area is another part of the color filter unit forming area;

developing and etching step, implementing developing and etching to reserve partial positive photoresist in the second area and entire positive photoresist in the third area, so as to form the color filter unit.

Furthermore, each second area is adjacent to the first area at an adjacent edge of the first area and corresponds to the color filter unit which is formed in the periphery of the first area and adjacent to the adjacent edge.

During manufacturing a first color pixel layer, the method includes the following steps:

photoresist coating step, forming a layer of first positive photoresist having a first color on the substrate, the first positive photoresist being used to form the color filter unit;

exposing step, entirely exposing and blocking exposure on a first area and a third area of the first positive photoresist respectively, the first area is an area surrounding the color filter unit forming area in which the color filter unit is to be formed, the third area is the color filter unit forming area;

developing and etching step, implementing developing and etching to reserve the first positive photoresist in the third area, so as to form the color filter unit.

During manufacturing a second color pixel layer, the method including the following steps:

photoresist coating step, forming a layer of second positive photoresist having a second color on the substrate on which a first color pixel layer has been formed, the second positive photoresist being used to form the color filter unit;

exposing step, entirely exposing, partially exposing and blocking exposure on a first area, a second area and a third area of the second positive photoresist respectively, the first area of the second positive photoresist is an area surrounding a color filter unit forming area in which the color filter unit is to be formed, the second area of the second positive photoresist is a part of the color filter unit forming area and adjacent to the first area of the second positive photoresist at a common edge, and the third area of the second positive photoresist is another part of the color filter unit forming area;

developing and etching step, implementing developing and etching to reserve partial second positive photoresist in the second area and entire second positive photoresist in the third area, so as to form the color filter unit.

Furthermore, the second area of the second positive photoresist corresponds to an area of a second color sub-pixel adjacent to a formed first color sub-pixel.

During manufacturing a third color pixel layer, the method including the following steps:

photoresist coating step, forming a layer of third positive photoresist having a third color on a substrate on which the second color pixel layer has been formed, the third positive photoresist being used to form the color filter unit;

exposing step, entirely exposing, partially exposing and blocking exposure on a first area , a second area and a third area of the third positive photoresist respectively, the first area of the third positive photoresist is an area surrounding the color filter unit forming area in which the color filter unit is to be formed, the second area of the third positive photoresist is a part of the color filter forming area and adjacent to the first area of the third positive photoresist at a common edge, the third area of the third positive photoresist is another part of the color filter unit forming area;

developing and etching step, implementing developing and etching to reserve partial third positive photoresist in the second area and entire third positive photoresist in the third area, so as to form the color filter unit.

Furthermore, the second areas of the third positive photoresist correspond to two sides of a third color sub-pixel adjacent to the corresponding second color sub-pixel and the first color sub-pixel respectively.

Furthermore, the first color, the second color and the third color are red, green and blue respectively.

The present disclosure can achieve the benefits of: by setting at least one partially blocked area, the exposure intensity is controlled, so as to decrease the corner segment difference.

### BRIEF DESCRIPTION OF THE DRAWINGS

FIG. 1 is a schematic diagram showing a structure of a color filter unit in the existing technology;

FIG. 2 is a schematic diagram showing a structure of a color filter unit of the present disclosure;

FIG. 3 is a schematic diagram showing a mask plate used for manufacturing a red pixel layer;

FIG. 4 is a schematic diagram showing a mask plate used for manufacturing a green pixel layer;

FIG. 5 is a schematic diagram showing a mask plate used for manufacturing a blue pixel layer.

### DETAILED DESCRIPTION

The structure and principle of the present disclosure will be described in details with reference to the accompanying figures, the disclosed embodiments are only used to explain the present disclosure, rather than limiting the protection scope of the present disclosure hereby.

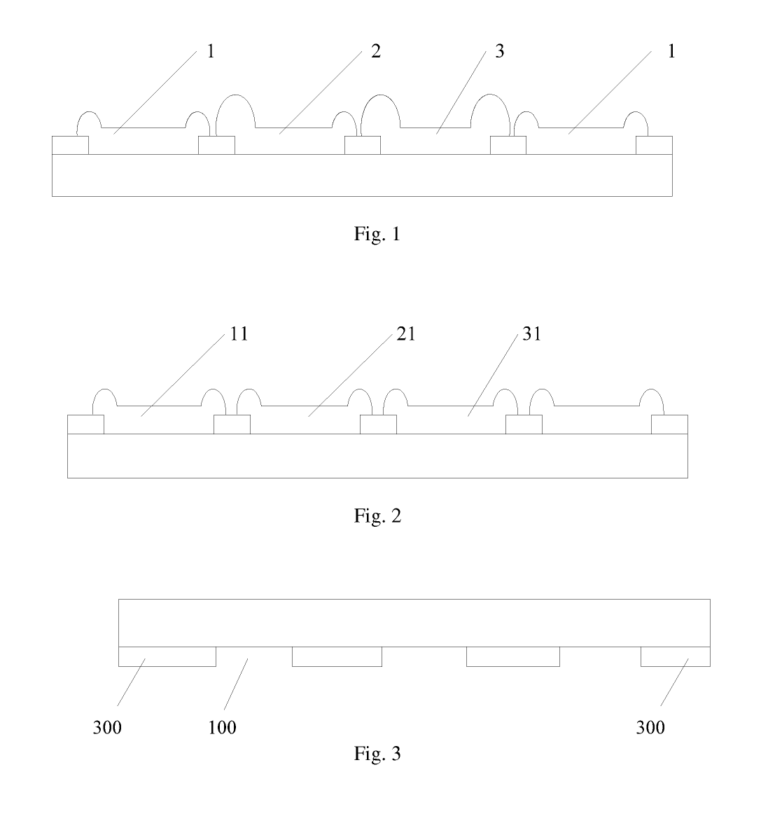

As shown in FIGS. 2- 5, the present embodiment provides a mask plate used for manufacturing a color filter unit of a color filter substrate, on the mask plate, the followings are formed:

an un-blocked area 100, through which light is capable to pass entirely, wherein the un-blocked area corresponds to a first area of positive photoresist surrounding a color filter unit forming area in which the color filter unit is to be formed;

at least one partially blocked area 200 through which the light is capable to pass partially, the partially blocked area corresponds to a second area of the positive photoresist, the second area is a part of the color filter unit forming area, the at least one partially blocked area 200 is adjacent to the un-blocked area 100 at a common edge.

an entirely blocked area 300 through which light cannot pass at all, the entirely blocked area corresponds to a third area of the positive photoresist, the third area is another part of the color filter unit forming area;

wherein reserved photoresist in the second area and the third area form the color filter unit.

The first area is a photoresist removed area; the third area is a photoresist entirely reserved area; the second area is adjacent to the first area at the common edge, whereas the second area is a photoresist partially reserved area corresponding to the partially blocked area through which the light can only partially pass, thus, by controlling the quantity of exposure, the film thickness is reduced, and the corner segment difference is decreased.

In the present embodiment, the second area corresponding to each partially blocked area 200 is adjacent to the first area corresponding to the un-blocked area 100 at an adjacent edge of the first area and corresponds to the color filter unit which is formed in the periphery of the first area and adjacent to the adjacent edge of the first area.

In general, the color filter unit is manufactured in an order of R, G and B, i.e. the red pixel layer, the green pixel layer and the blue pixel layer are successively manufactured. However, it is not limited. In the present embodiment, in the following, the mask plate used for manufacturing the color filter unit of the color filter substrate is described in an order of R, G, B.

In the present embodiment, the mask plate used for manufacturing the color filter unit of the color filter substrate is aimed to solve the problem of segment difference during manufacturing the green pixel layer and the blue pixel layer, therefore, it is adaptive for the mask plate for manufacturing the green pixel layer and the mask plate for manufacturing the blue pixel layer.

Each of the red pixel layer, the green pixel layer and the blue pixel layer includes multiple sub-pixels.

During manufacturing the red pixel layer, the mask plate includes the un-blocked area 100 and the entirely blocked area 300. The un-blocked area 100 corresponds to the first area of the positive photoresist surrounding the color filter unit forming area of the color filter unit. The entirely blocked area 300 corresponds to the third area of the positive photoresist which is to be the color filter unit forming area, as shown in FIG. 3.

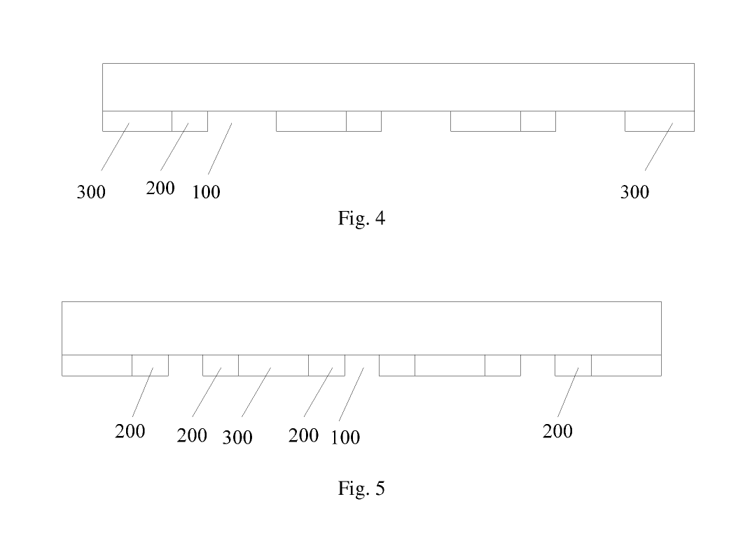

During manufacturing the green pixel layer, since the red pixel layer has been formed, one side of a first green sub-pixel 21 is adjacent to the corresponding first red sub-pixel 11 formed in the red pixel layer, i.e., the partially blocked area 200 on the mask plate is adjacent to the un-blocked area 100 at a common edge. Due to the first red sub-pixel 11 is existing, the film layer of the first green sub-pixel 21 at the side adjacent to the corresponding first red sub-pixel 11 is thicker, which leads to increasing of the segment difference at the side of the first green sub-pixel 21 adjacent to the corresponding first red sub-pixel 11. Therefore, the second area corresponding to the side of the first green sub-pixel 21 adjacent to the corresponding first red sub-pixel 11 is configured to correspond to the partially blocked area 200 of the mask plate, as shown in FIG. 4, so as to reduce the film thickness and decrease the corner segment difference.

In the present embodiment, the partially blocked area adopts a semi-transparent film to control the quantity of exposure, so as to reduce the film thickness and decrease the corner segment difference.

During manufacturing the blue pixel layer, due to both the red pixel layer and the green pixel layer have already been formed, i.e., the first green sub-pixel 21 and the first red sub-pixel 11 have been formed at both sides of the first blue sub-pixel 31 respectively. In order to prevent the segment differences at the both sides of the first blue sub-pixel 21 adjacent to the first green sub-pixel 21 and the first red sub-pixel 11 respectively from increasing, the partially blocked areas 200 corresponding to the second areas at both sides of the first blue sub-pixel 31 are arranged on the mask plate, as shown in FIG. 5, so as to control the quantity of exposure, thus to reduce the film thickness and decrease the corner segment difference .

In the present embodiment, the partially blocked area adopts a semi-transparent film to control the quantity of exposure, so as to reduce the film thickness and decrease the corner segment difference.

The present disclosure also provides a method for manufacturing a color filter unit of the color filter substrate, including:

photoresist coating step, forming a layer of positive photoresist on a substrate, the positive photoresist being used to form the color filter unit;

exposing step, entirely exposing, partially exposing and blocking exposure on the first area, the second area and the third area of the positive photoresist respectively, the first area being an area surrounding a color filter unit forming area in which the color filter unit is to be formed, the second area is a part of the color filter unit forming area and is adjacent to the first area at a common edge, and the third area is another part of the color filter unit forming area;

developing and etching step, implementing developing and etching process to reserve partial positive photoresist in the second area and entire positive photoresist in the third area, so as to form the color filter unit.

In the present embodiment, each second area is adjacent to the first area at an adjacent edge of the first area and corresponds to the color filter unit which is formed in the periphery of the first area and adjacent to the adjacent edge.

In the present embodiment, the method for manufacturing the color filter unit of the color filter substrate is specifically described in an order of a first color (e.g. red) pixel layer, a second color (e.g. green) pixel layer, and a third color (e.g. blue) pixel layer. It should be noted, in an actual manufacturing process, the order of manufacturing the color filter unit is not limited to the above.

During manufacturing the first color (e.g. red) pixel layer, the method for manufacturing the color filter unit of the color filter substrate includes the following steps:

photoresist coating step, forming a layer of first positive photoresist having a first color on a substrate, the first positive photoresist being used to form the color filter unit;

exposing step, entirely exposing and blocking exposure on a first area and a third area of the first positive photoresist respectively, the first area is an area surrounding the color filter unit forming area in which the color filter unit is to be formed, the third area is the color filter unit forming area;

developing and etching step, implementing developing and etching process to reserve the first positive photoresist in the third area, so as to form the color filter unit.

During manufacturing the second color (e.g. green) pixel layer, the method for manufacturing the color filter unit of the color filter substrate includes the following steps:

photoresist coating step, forming a layer of second positive photoresist having a second color on the substrate on which a first color pixel layer has been formed, the second positive photoresist being used to form the color filter unit;

exposing step, entirely exposing, partially exposing and blocking exposure on the first area, the second area and the third area of the second positive photoresist respectively, the first area is an area surrounding the color filter unit forming area in which the color filter unit is to be formed, the second area is a part of the color filter unit forming area and is adjacent to the first area at a common edge, and the third area is another part of the color filter unit forming area;

developing and etching step, implementing developing and etching process to reserve partial second positive photoresist in the second area and entire second positive photoresist in the third area, so as to form the color filter unit.

In the present embodiment, after the green pixel layer is formed, the second area corresponds to an area of the first green sub-pixel 21 adjacent to the formed first red sub-pixel 11.

During manufacturing the third color (e.g. blue) pixel layer, the method for manufacturing the color filter unit of the color filter substrate includes the following steps:

photoresist coating step, forming a layer of third positive photoresist having a third color on a substrate on which the second color pixel layer has been formed, the third positive photoresist being used to form the color filter unit;

exposing step, entirely exposing, partially exposing and blocking exposure on a first area, a second area and a third area of the third positive photoresist respectively, the first area is an area surrounding the color filter unit forming area in which the color filter unit is to be formed, the second area is a part of the color filter unit forming area and is adjacent to the first area at the common edge, and the third area is another part of the color filter unit forming area ;

developing and etching step, implementing developing and etching process to reserve partial third positive photoresist in the second area and entire third positive photoresist in the third area, so as to form the color filter unit.

In the present embodiment, after the blue pixel layer is formed, the second area corresponds to the both sides of the first blue sub-pixel 31 adjacent to the corresponding first green sub-pixel 21 and the first red sub-pixel 11 respectively.

The above are preferred embodiments of the present disclosure, it should be noted that, for those ordinary skilled in the art, various improvements and modifications can be made without departing from the principle of the present disclosure, and which are also should be considered as within the protection scope of the present disclosure.

1. A mask plate used for manufacturing a color filter unit of a color filter substrate, comprising:
an un-blocked area, through which light is able to entirely pass, the un-blocked area corresponding to a first area of positive photoresist surrounding a color filter forming area in which the color filter unit is to be formed;
at least one partially blocked area, through which the light is able to partially pass, the at least one partially blocked area corresponding to a second area of the positive photoresist, the second area is a part of the color filter forming area, the at least one partially blocked area is adjacent to the un-blocked area at a common edge;
an entirely blocked area, through which the light cannot pass at all, the entirely blocked area corresponding to a third area of the positive photoresist, the third area is another part of the color filter unit forming area;
wherein the color filter unit is formed by photoresist reserved in the second area and the third area.

2. The mask plate according to claim 1, wherein, the second area corresponding to each partially blocked area is adjacent to the first area at an adjacent edge of the first area and corresponds to a color filter unit which is formed in the periphery of the first area and adjacent to the adjacent edge.

3. A method for manufacturing a color filter unit of a color filter substrate, comprising:
photoresist coating step, forming a layer of positive photoresist on a substrate, the positive photoresist being used to form the color filter unit;
exposing step, entirely exposing, partially exposing and blocking exposure on the a first area, a second area and a third area of the positive photoresist respectively, the first area being an area surrounding a color filter unit forming area in which the color filter unit is to be formed, the second area is a part of the color filter unit forming area and is adjacent to the first area at a common edge, and the third area is another part of the color filter unit forming area;
developing and etching step, implementing developing and etching to reserve partial positive photoresist in the second area and entire positive photoresist in the third area, so as to form the color filter unit.

4. The method according to claim 3, wherein each second area is adjacent to the first area at an adjacent edge of the first area and corresponds to the color filter unit which is formed in the periphery of the first area and adjacent to the adjacent edge.

5. The method according to claim 3, during manufacturing a first color pixel layer, the method comprises:
photoresist coating step, forming a layer of first positive photoresist having a first color on the substrate, the first positive photoresist being used to form the color filter unit;
exposing step, entirely exposing and blocking exposure on a first area and a third area of the first positive photoresist respectively, the first area is an area surrounding the color filter unit forming area in which the color filter unit is to be formed, the third area is the color filter unit forming area;
developing and etching step, implementing developing and etching to reserve the first positive photoresist in the third area, so as to form the color filter unit.

6. The method according to claim 5, during manufacturing a second color pixel layer, the method comprises:
photoresist coating step, forming a layer of second positive photoresist having a second color on the substrate on which a first color pixel layer has been formed, the second positive photoresist being used to form the color filter unit;
exposing step, entirely exposing, partially exposing and blocking exposure on a first area, a second area and a third area of the second positive photoresist respectively, the first area of the second positive photoresist is an area surrounding a color filter unit forming area in which the color filter unit is to be formed, the second area of the second positive photoresist is a part of the color filter unit forming area and adjacent to the first area of the second positive photoresist at a common edge, and the third area of the second positive photoresist is another part of the color filter unit forming area;
developing and etching step, implementing developing and etching to reserve partial second positive photoresist in the second area and entire second positive photoresist in the third area, so as to form the color filter unit.

7. The method according to claim 6, wherein, the second area of the second positive photoresist corresponds to an area of a second color sub-pixel adjacent to a formed first color sub-pixel.

8. The method according to claim 6, during manufacturing a third color pixel layer, the method comprises:
photoresist coating step, forming a layer of third positive photoresist having a third color on a substrate on which the second color pixel layer has been formed, the third positive photoresist being used to form the color filter unit;
exposing step, entirely exposing, partially exposing and blocking exposure on a first area, second areas, and a third area of the third positive photoresist respectively, the first area of the third positive photoresist is an area surrounding the color filter unit forming area in which the color filter unit is to be formed, the second area of the third positive photoresist is a part of the color filter forming area and adjacent to the first area of the third positive photoresist at a common edge, the third area of the third positive photoresist is another part of the color filter unit forming area;
developing and etching step, implementing developing and etching to reserve partial third positive photoresist in the second area and entire third positive photoresist in the third area, so as to form the color filter unit.

9. The method according to claim 8, wherein, the second areas of the third positive photoresist correspond to two sides of a third color sub-pixel adjacent to the corresponding second color sub-pixel and the first color sub-pixel respectively.

10. The method according to claim 8, wherein, the first color, the second color and the third color are red, green and blue respectively.
